(19) United States
(12) Patent Application Publication
(10) Pub. No.: US 2012/0027916 A1
(43) Pub. Date: Feb. 2, 2012

(54) ARRANGEMENT AND METHOD FOR MEASUREMENT OF THE TEMPERATURE AND OF THE THICKNESS GROWTH OF SILICON RODS IN A SILICON DEPOSITION REACTOR

(75) Inventors: Vollmar Wilfried, Soest-Deiringsen (DE); Frank Stubhan, Ehingen (DE)

(73) Assignee: CENTROTHERM SITEC GMBH, Blaubeuren (DE)

(21) Appl. No.: 13/145,933

(22) PCT Filed: Jan. 28, 2010
(86) PCT No.: PCT/EP2010/050988

§ 371 Date: Oct. 11, 2011

(30) Foreign Application Priority Data
Jan. 29, 2009 (DE) 10 2009 006 600.4
Feb. 24, 2009 (DE) 10 2009 010 086.5

(51) Int. Cl. C23C 16/52

(52) U.S. Cl. 427/9; 118/712; 118/713

(57) ABSTRACT

An arrangement for measurement of temperature and thickness growth of silicon rods in a silicon deposition reactor employs a temperature measurement device located outside the reactor. Continuous temperature measurement and measurement of the thickness growth throughout the entire deposition process is achieved with a contactlessly operating temperature measurement device arranged outside the silicon deposition reactor in front of a viewing window. The temperature measurement device can be pivoted horizontally about a rotation axis by a rotating drive. The pivoting axis runs parallel to a longitudinal axis of the silicon rod, and the central axis of the temperature measurement device runs through the pivoting axis.

The invention relates to an arrangement and a method for measurement of the temperature and of the thickness growth of silicon rods in a silicon deposition reactor by means of a temperature measurement device which is located outside the reactor.

The manufacturing process for polycrystalline silicon is based on a method in which gaseous trichlorosilane is passed together with hydrogen into a vacuum reactor in which thin silicon rods have previously been arranged as the raw material, and are electrically heated to temperatures of around 1100 degrees Celsius. This method has become known as the so-called SIEMENS method. In this case, strict attention must be paid to not reaching the melting temperature of silicon. In this case, silicon is deposited on the silicon rods, with the silicon being created in a chemical reaction from the trichlorosilane. The pillars of polysilicon which are created in this way are then available for further processing.

The pillars are once again broken down into relatively small chunks for the photovoltaic industry, and are then melted in quartz crucibles and, if required, are reshaped into monocrystalline or polycrystalline blocks, from which the blanks for solar modules are then manufactured.

One critical factor in this process is the temperature control of the thin silicon rods in the silicon deposition reactor during the coating process, during which the temperature must be kept within a predetermined temperature range around 1100° C., and it is absolutely essential to stop this process if over-temperatures occur, which would lead to fracture of a silicon rod and to stopping of the deposition process, and in the event of excessively low temperatures, which would not lead to optimum deposition of the silicon.

One possible way to comply with these conditions would be continuous manual visual inspection, which would be extremely complex and would have to be carried out at least during the first hours of the process.

One or more viewing windows are located for this purpose in the silicon deposition reactor and allow observation with approximate values by manual viewing and personal estimation. This must be done all the time and, of course, does not lead to reproducible, sufficiently reliable results. This is because fatal consequences can result from the nominal temperature being briefly exceeded.

The invention is based on the object of providing an arrangement and a method for measurement of the temperature and of the thickness growth of silicon rods in a silicon deposition reactor, in order to allow sufficiently accurate continuous measurement of the temperature and of the thickness growth throughout the entire deposition process.

The object on which the invention is based is achieved in that a contactlessly operating temperature measurement device is provided for the temperature measurement and is arranged outside the silicon deposition reactor in front of a viewing window, in that the temperature measurement device can be pivoted horizontally about a rotation axis by means of a rotating drive, wherein the rotation axis runs parallel to the longitudinal axis of the silicon rod, and wherein the centre axis of the temperature measurement device runs through the pivoting axis. The thermal radiation emerging from a silicon rod is measured during this process.

In one development of the invention, the rotation axis is located outside the reactor wall of the silicon deposition reactor, in front of the viewing window.

In one variant of the invention, the reaction axis is arranged within the silicon deposition reactor, behind the viewing window, thus making it possible to record a wider pivoting range in the silicon deposition reactor.

Furthermore, the viewing window is cooled by being provided with liquid cooling. The corruption of the measurement temperature resulting from this can be corrected purely by calculation.

In one particular development, a rotatable polarization filter is arranged between the temperature measurement device and the viewing window, or at least in front of the temperature measurement device. This makes it possible to mask out or to minimize reflections on the inner wall of the silicon deposition reactor. This allows incorrect measurements to be avoided, thus improving the measurement accuracy.

In a further refinement of the invention, the temperature measurement device is a pyrometer whose measurement data is stored for further processing and is displayed on a monitor, wherein a grid can be superimposed on the data displayed on the monitor for better orientation.

The temperature measurement device may also be a thermal imaging camera which can pivot or may also possibly be stationary, wherein the measurement data, that is to say the temperature profile over time and the temperature profile over the angle, are in both cases evaluated electronically.

Furthermore, the temperature measurement device is coupled to a rotating drive for positioning of the rotation axis behind the sight glass, which rotating drive is located below a tubular connecting stub, which projects from the reactor wall and in which a sight glass is located.

The arrangement according to the invention can advantageously be used for deposition reactors or other thermal coating processes.

The object on which the invention is based is also achieved by a method for measurement of the temperature and of the thickness growth of thin silicon rods in a silicon deposition reactor, by
arrangement of thin silicon rods in the silicon deposition reactor, removal of the oxygen and starting of the deposition process by integration of the thin silicon rods in an electrical circuit, and introduction of trichlorosilane in the silicon deposition reactor,
scanning of the thin silicon rods by a temperature measurement device which is located outside the silicon deposition reactor, and selection of one of the thin silicon rods and focusing of the pyrometer onto the selected thin silicon rod,
recording a temperature curve plotted against the time and simultaneous measurement of the thickness growth by horizontally pivoting the pyrometer until a sudden light/dark change is identified and pivoting the pyrometer in the opposite pivoting direction until a further sudden light/dark change is identified,
calculation of the diameter of the coated thin silicon rod from the pivoting angle, and
repetition of the measurement of the thickness growth at intervals, and ending the deposition process after the coated silicon rod has reached a predetermined thickness.

The intervals may in this case also be zero, that is to say measurements are carried out without any interruption, or they may assume discrete values, thus allowing measurements to be carried out at defined intervals.

A thin silicon rod which is located closest to the viewing window is preferably selected, after its integration into an electrical circuit.

In one particular refinement of the invention, any reflections which may be present on the inner wall of the silicon deposition reactor before the start of the scanning process are masked out by a polarization filter, in that this polarization filter is rotated until the reflections have disappeared, or have at least been reduced.

The arrangement according to the invention can advantageously be used for deposition reactors with thermally dependent layer growth.

The particular advantages of the invention are that the coating process can be carried out from the start with automatic temperature detection and thickness measurement, thus making it possible to avoid over-temperatures which would lead to the process being shut down. In addition, this makes it possible to avoid excessively low temperatures, which would lead to non-optimum layer deposition.

Furthermore, the coating process is optimized in that it can be ended when the silicon rods reach a nominal thickness. In addition, the use of media is optimized in that the gas processes can be controlled automatically with the rod diameter that is achieved, because correspondingly more trichlorosilane must be supplied as the thickness of the silicon rods increases, for constant thickness growth.

The arrangement according to the invention makes it possible to determine the deposition thickness and the layer thickness increase over time without any problems, to be precise using the considerable sudden temperature change on the external circumference of the silicon rod.

The invention will be explained in more detail in the following text with reference to one exemplary embodiment.

In the associated drawing figures

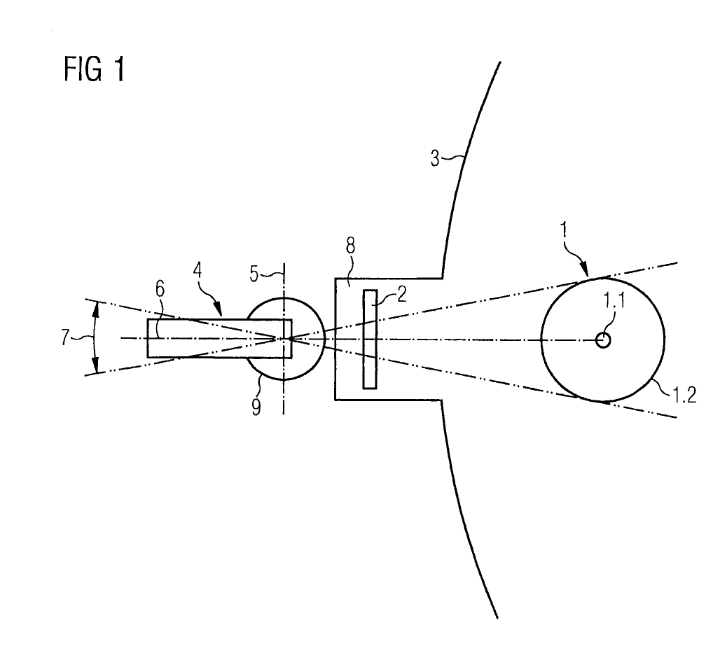

FIG. 1: shows a schematic plan view of an arrangement according to the invention for temperature measurement of silicon rods;

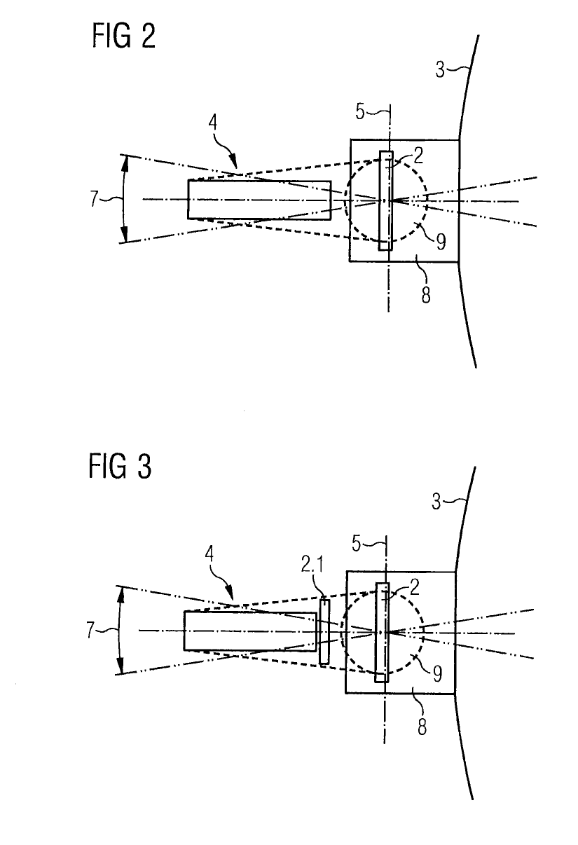

FIG. 2: shows a schematic plan view of a variant as shown in FIG. 1, in which the pivoting axis of the temperature measurement device is located behind the sight glass; and

FIG. 3: shows a schematic plan view of the variant as shown in FIG. 2, with a polarization filter added.

According to FIG. 1, the arrangement for temperature measurement of silicon rods 1 in a silicon deposition reactor through a viewing window 2 in the reactor wall 3 contains a contactlessly operating temperature measurement device 4 which can be pivoted about a pivoting axis 5. The pivoting axis 5 runs parallel to the longitudinal axis 6 of the silicon rod 1. Furthermore, the longitudinal axis 6 of the temperature measurement device 4 runs through the pivoting axis 5.

FIG. 1 shows the silicon rod 1 in two states, specifically as a thin silicon rod 1a and as a silicon rod 1b after the end of the process.

In the variant shown in FIG. 1, the pivoting axis 5 is located outside the reactor wall 3 of the silicon deposition reactor, in front of the viewing window 2, which is accommodated in a tubular connecting stub 8 which projects out of the tube wall 3.

Motor adjustment in the form of a rotating drive 9 is provided for the pivoting drive for the temperature measurement device 4.

The arrangement according to the invention allows the silicon rod 1 to be scanned permanently or at time intervals in a simple manner during the deposition process, to be precise to determine the temperature and the thickness growth. Since scanning over the width of the silicon rod 1 is possible, the thickness growth of the silicon rod 1 can be continuously checked during the deposition process on the basis of the sudden temperature change at the side edge of the silicon rod 1.

Furthermore, this allows the use of media to be optimized, in that the gas processes can be automatically matched to the rod diameter that has been achieved, because correspondingly more trichlorosilane must be supplied as the thickness of the silicon rods increases, with constant thickness growth. The process can therefore be started with a minimal required amount of trichlorosilane, in which case the amount can then be matched to the increasing diameter of the silicon rod.

The achieved thickness can be calculated from the distance between the pivoting axis 5 and the silicon rod 1, and the determined pivoting angle.

FIG. 2 shows a schematic plan view of a variant of the invention in which the pivoting axis 5 is located behind the viewing window 2, that is to say within the silicon deposition reactor, thus making it possible to achieve a greater pivoting angle.

In order to position the pivoting axis 5 behind the sight glass, the temperature measurement device 4 is coupled to a rotating drive 9 which is located under the sight glass.

A pyrometer whose measurement data can be stored and displayed on a monitor is particularly suitable for use as the temperature measurement device 4, on which a grid can be superimposed in order to better illustrate the displayed data and limit values.

Instead of a pyrometer, a thermal imaging camera can also be used, and can also be arranged to be stationary if appropriately programmed.

Furthermore, a rotatable polarization filter 2.1 can be arranged between the pyrometer and the viewing window 2, thus making it possible to mask out disturbing reflections on the inner wall of the reactor, or at least to minimize them, by appropriately rotating the polarization filter 2.1 until the reflections disappear or are minimized (FIG. 3). This makes it possible to achieve a particularly high measurement accuracy.

The arrangement according to the invention allows an automated method for measurement of the temperature and of the thickness growth of thin silicon rods in a silicon deposition reactor.

For this purpose, thin silicon rods 1.1 are first of all arranged in the silicon deposition reactor, and oxygen is removed from the silicon deposition reactor. The deposition process can then be started by integration of the thin silicon rods 1.1 in an electrical circuit, and introduction of trichlorosilane. The thin silicon rods 1.1 are heated electrically to a temperature of around 1100° C., that is to say the deposition temperature.

The thin silicon rods 1.1 are then scanned by a temperature measurement device 4, for example a pyrometer, which is located outside the silicon deposition reactor, and one of the thin silicon rods 1.1 is selected, with the pyrometer being focused on this thin silicon rod 1.1.

A temperature curve is then recorded over time, and the simultaneous or subsequent measurement of the thickness growth of the thin silicon rods 1.1 is carried out by horizontally pivoting the temperature measurement device 4 until a sudden light/dark change is identified and pivoting the temperature measurement device 4 in the opposite pivoting direction until a further sudden light/dark change is identified. The diameter of the coated thin silicon rod 1.1 can then be calculated easily from the distance between the pivoting axis and the silicon rod, and the measured pivoting angle.

In order to improve the accuracy of the measurement process, reflections on the inner wall of the silicon deposition reactor before the start of the scanning process should be masked out and this can be done by means of a polarization filter, by rotating this polarization filter until the reflection has disappeared or has at least been reduced.

The thickness growth is measured either at uniform time intervals or continuously, such that the silicon deposition process is ended once the coated thin silicon rod 1.2 reaches a predetermined thickness.

In principle, of course, it is also possible to measure a plurality of thin silicon rods 1.1 staggered in time.

This method on the one hand ensures that a critical temperature is never exceeded, while on the other hand optimizes the deposition process by the capability to stop this process when the silicon rods reach the nominal thickness.

In principle, it is also possible to pivot the temperature measurement device 4 about a horizontal axis, which should preferably be located behind the viewing window. This makes it possible to mask out reflections from the opposite reactor wall, by pivoting the temperature measurement device 4 somewhat downwards or upwards.

### LIST OF REFERENCE SYMBOLS

1 Silicon rod
1.1 Thin silicon rod
1.2 Silicon rod after the end of deposition
2 Viewing window
2.1 Polarization filter
3 Reactor wall
4 Temperature measurement device
5 Pivoting axis
6 Longitudinal axis
7 Rotation angle
8 Tubular connecting stub
9 Rotating drive

1. Arrangement for measurement of temperature and thickness growth of silicon rods in a silicon deposition reactor through a viewing window, comprising: a contactlessly operating temperature measurement device for the temperature measurement arranged outside the silicon deposition reactor in front of the viewing window, and a rotating device for pivoting the temperature measurement device horizontally about a pivoting axis, wherein the pivoting axis runs parallel to a longitudinal axis of the silicon rod, and wherein a central axis of the temperature measurement device runs through the pivoting axis.

2. Arrangement according to claim 1, wherein the pivoting axis is arranged outside a wall of the silicon deposition reactor, in front of the viewing window.

3. Arrangement according to claim 1, wherein the pivoting axis is arranged within the silicon deposition reactor, behind the viewing window.

4. Arrangement according to claim 1, wherein the viewing window is cooled.

5. Arrangement according to claim 4, wherein the viewing window is provided with liquid cooling.

6. Arrangement according to claim 1, wherein a rotatable polarization filter is arranged between the temperature measurement device and the viewing window.

7. Arrangement according to claim 1, wherein the temperature measurement device comprises a pyrometer.

8. Arrangement according to claim 7, further comprising a memory for storing measurement data of the pyrometer and a monitor for displaying the measurement data.

9. Arrangement according to claim 8, wherein a grid is superimposed on the data displayed on the monitor.

10. Arrangement according to claim 1, wherein the temperature measurement device comprises a thermal imaging camera.

11. Arrangement according to claim 10, wherein the thermal imaging camera is stationary.

12. Arrangement according to claim 1 wherein the temperature measurement device is coupled to the rotating drive to position the pivoting axis behind the viewing window, the rotating drive is located below the viewing window, and the viewing window is arranged in a tubular connecting stub located on a wall of the reactor.

13. The arrangement according to claim 1, in combination with the deposition reactor.

14. Method for measurement of temperature and thickness growth of thin silicon rods in a silicon deposition reactor, comprising:
arranging the thin silicon rods in the silicon deposition reactor, removal of oxygen from the reactor and starting of a deposition process by integration of the thin silicon rods in an electrical circuit, and introducing tricholorosilane into the reactor to coat the rods,
scanning of the thin silicon rods by a temperature measurement device located outside the silicon deposition reactor, and selecting one coated rod of the thin silicon rods being coated and focusing of the temperature measurement device onto the one coated rod,
recording a temperature curve plotted against time for the one coated rod and simultaneously measuring the thickness growth of the one coated rod by horizontally pivoting the temperature measurement device until a sudden light/dark change is identified and pivoting the temperature measurement device in an opposite pivoting direction until a further sudden light/dark change is identified,
calculating diameter of the one coated rod from pivoting angle and distance between the pivoting axis and the silicon rod, and
repeating the measurement of the thickness growth at predetermined intervals, and ending the deposition process after the one coated rod has reached a predetermined thickness.

15. Method according to claim 14, wherein the intervals are ≧zero.

16. Method according to claim 14, wherein a plurality of thin silicon rods are selected and measured, staggered in time.

17. Method according to claim 14, wherein reflections on an inner wall of the silicon deposition reactor before start of the scanning masked out by a polarization filter.
